(19) United States
(12) Patent Application Publication
(10) Pub. No.: US 2023/0352454 A1
(43) Pub. Date: Nov. 2, 2023

(54) BONDED BODY, METHOD OF MANUFACTURING THE BONDED BODY, AND LIGHT-EMITTING DEVICE

(71) Applicant: AGC Inc., Tokyo (JP)

(72) Inventors: Yohei NAGAO, Tokyo (JP); Takenori SOMEYA, Tokyo (JP)

(73) Assignee: AGC Inc., Tokyo (JP)

(21) Appl. No.: 18/330,495

(22) Filed: Jun. 7, 2023

Related U.S. Application Data
(63) Continuation of application No. PCT/JP2021/044853, filed on Dec. 7, 2021.

(30) Foreign Application Priority Data
Dec. 18, 2020 (JP) 2020-209960
Sep. 27, 2021 (JP) 2021-156952

(51) Int. Cl. H01L 33/44; H01L 33/48; H01L 25/075; H01L 33/00; H01L 33/58

(52) U.S. Cl. CPC H01L 25/075; H01L 33/0083; H01L 33/44; H01L 33/486; H01L 33/58

(57) ABSTRACT

A bonded body includes a first base material; a second base material; an inorganic film for bonding the first base material and the second base material; and a semiconductor layer formed on a surface opposite to a bonding surface of the second base material, the bonding surface of the second base material facing the first base material, wherein the first base material is a glass with a SiO₂ content of 70 mol% or less, and the inorganic film includes a silicon oxide film formed on a bonding surface of the first base material, the bonding surface of the first base material facing the second base material.

### CROSS-REFERENCE TO RELATED APPLICATION

This application is a continuation of International Application PCT/JP2021/044853, filed on Dec. 7, 2021, which is based on and claims priority to Japanese Patent Application No. 2020-209960 filed on Dec. 18, 2020, with the Japan Patent Office, and to Japanese Patent Application No. 2021-156952 filed on Sep. 27, 2021, with the Japan Patent Office. The contents of these applications are incorporated herein by reference in their entirety.

### BACKGROUND OF THE INVENTION

### 1. Field of the Invention

The present disclosure relates to a bonded body, a method of manufacturing the bonded body, and a light-emitting device.

### 2. Description of the Related Art

Patent Document 1 discloses a bonding method of bonding two substrates. The bonding method includes hydrophilizing at least one of the bonding surfaces of the two substrates to be bonded to each other, and bonding the two substrates after hydrophilization. Hydrophilization includes reactive ion etching using an oxygen gas, reactive ion etching using a nitrogen gas, and irradiation of nitrogen radicals.

Patent document 2 discloses a bonding method of bonding two substrates. The bonding method includes forming a thin film of metal oxide on the bonding surfaces of both or either of a pair of substrates, and contacting and bonding the bonding surfaces of the substrates with each other through the thin film. The substrate is glass containing SiO₂, tempered glass, etc. An aluminum oxide film is used as a thin film in the examples.

The inventor applied the technique described in Patent Document 1, the so-called sequential plasma method, to bonding of glass to glass, and bonding of glass to ceramic, which will be described in detail later. The sequential plasma method is a technique to modify the bonding surface of glass, etc.

The modified bonding surface comes into contact with steam or water, etc., and OH groups, which are hydrophilic groups, are generated on the bonding surface. Thereafter, hydrogen bonds between the OH groups occur during the bonding, and high bonding strength is obtained. Annealing treatment may be performed after the bonding. Annealing turns the hydrogen bonds into covalent bonds and results in higher bonding strength.

As a result of experiments conducted by the present inventor, when the bonding surface of quartz glass with a SiO₂ content of 100 mol% was modified using the sequential plasma method, a higher bonding strength was obtained compared to a case when the bonding surface of quartz glass was modified using only reactive ion etching with oxygen gas.

On the other hand, when the bonding surface of glass with a SiO₂ content of 70 mol% or less was modified using the sequential plasma method, a similar bonding strength was obtained compared to a case when the bonding surface of glass was modified using only reactive ion etching with oxygen gas.

### RELATED-ART DOCUMENTS

### Patent Documents

[Patent document 1] WO 2018/084285
[Patent document 2] WO 2019/131490

### SUMMARY OF THE INVENTION

According to an aspect of the present disclosure, it is desirable to provide a technique for improving the bonding strength of glass with low SiO₂ content.

According to an aspect of the present disclosure, a bonded body includes
a first base material;
a second base material;
an inorganic film for bonding the first base material and the second base material; and
a semiconductor layer formed on a surface opposite to a bonding surface of the second base material, the bonding surface of the second base material facing the first base material, wherein the first base material is a glass with a SiO₂ content of 70 mol% or less, and the inorganic film includes a silicon oxide film formed on a bonding surface of the first base material, the bonding surface of the first base material facing the second base material.

### BRIEF DESCRIPTION OF THE DRAWINGS

FIG. 1 is a cross-sectional view illustrating a bonded body according to an embodiment.

FIG. 2 is a cross-sectional view illustrating states of first and second base materials before bonding in FIG. 1.

FIG. 3 is a flowchart illustrating a method of manufacturing a bonded body according to one embodiment.

FIG. 4 is a cross-sectional view illustrating a bonded body according to a first modification.

FIG. 5 is a cross-sectional view illustrating a bonded body according to a second modification.

FIG. 6 is a cross-sectional view illustrating a bonded body according to a third modification.

FIG. 7 is a cross-sectional view illustrating a bonded body according to a fourth modification.

FIG. 8 is a cross-sectional view illustrating an example of a state of a lens serving as the first base material before bonding.

FIG. 9 is a cross-sectional view illustrating an example of a method of measuring a bonding strength.

FIG. 10 is a cross-sectional view illustrating another example of a state of the lens as the first base material before bonding.

FIG. 11 is a cross-sectional view illustrating a light-emitting device according to one embodiment.

FIG. 12 is a cross-sectional view illustrating a light-emitting device according to a first modification.

FIG. 13 is a cross-sectional view illustrating a light-emitting device according to a second modification.

FIG. 14 is a cross-sectional view illustrating a die shear test of Example 14.

FIG. 15 is a cross-sectional view illustrating a die shear test of Example 15.

### DESCRIPTION OF THE EMBODIMENTS

In the following, embodiments of the disclosure are described with reference to the drawings. Throughout the drawings, the same elements are assigned the same reference numerals and duplicated descriptions may be omitted. Also, in this specification, a numerical range expressed using “to” includes the lower limit value and the upper limit value before and after “to”. In the specification, the term “plan view” means to view from a direction perpendicular to a bonding surface.

The inventor applied the technique described in Patent Document 1, the so-called sequential plasma method, to bonding of glass to glass, and also to bonding of glass to ceramic, which will be described in detail later. The sequential plasma method includes, for example, reactive ion etching using an oxygen gas, reactive ion etching using a nitrogen gas, and irradiation of nitrogen radicals.

In the following, reactive ion etching (Reactive Ion Etching: RIE) using an oxygen gas is also referred to as “oxygen RIE”. Reactive ion etching using a nitrogen gas is also referred to as “nitrogen RIE”. The sequential plasma method may include nitrogen RIE and irradiation of nitrogen radicals, and not required to include oxygen RIE.

The sequential plasma method modifies the bonding surface of glass or the like. The modified bonding surface comes into contact with water vapor or water or the like, and OH groups as hydrophilic groups are generated on the bonding surface. Thereafter, hydrogen bonds between the OH groups occur during bonding, and high bonding strength is obtained. After bonding, annealing treatment may be performed. Annealing turns the hydrogen bonds into covalent bonds, resulting in higher bonding strength.

As a result of experiments conducted by the present inventor, when the bonding surface of quartz glass with a SiO₂ content of 100 mol% was modified using the sequential plasma method, a higher bonding strength was obtained compared with the case when only oxygen RIE was used.

On the other hand, when the bonding surface of glass with a SiO₂ content of 70 mol% or less was modified using the sequential plasma method, merely a similar bonding strength was obtained compared with the case when only oxygen RIE was used.

The inventor conducted further experiments and found that the bonding strength could be improved by the sequential plasma method if a silicon oxide film was formed on the bonding surface of the glass when at least one of the two substrates to be bonded to each other was a glass with a low SiO₂ content.

The silicon oxide film before surface modification contains almost no impurities other than oxygen and silicon, as in quartz glass. Therefore, when the bonding surface of the silicon oxide film is modified by the sequential plasma method, the bonding strength can be as high as when the bonding surface of quartz glass were modified by the sequential plasma method.

The silicon oxide film after bonding contains 1 atomic% or more of nitrogen atoms by energy-dispersive X-ray analysis. The nitrogen atom content is preferably 1.5 atomic% or more. The nitrogen atom content is preferably 10 atomic% or less.

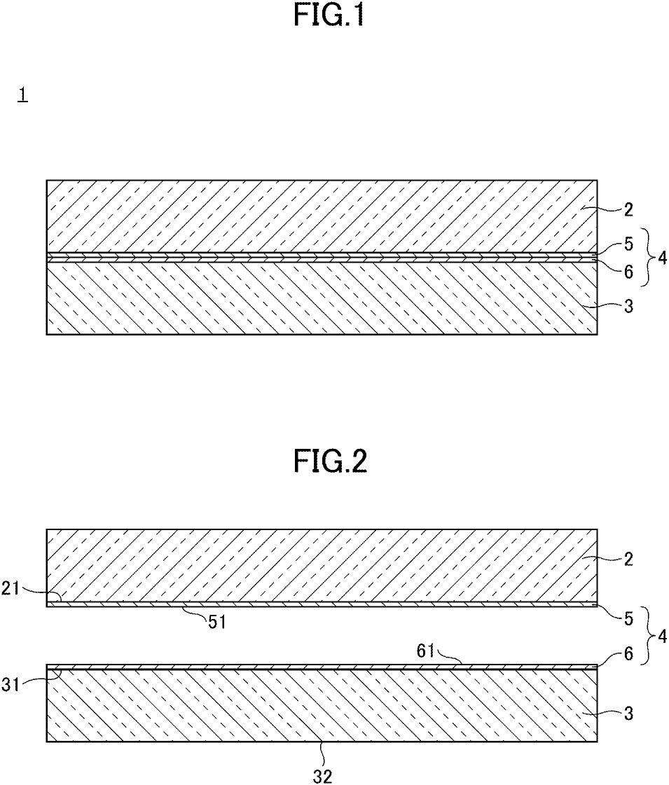

As illustrated in FIG. 1, a bonded body 1 includes a first base material 2, a second base material 3, and an inorganic film 4. The inorganic film 4 bonds the first base material 2 and the second base material 3. The inorganic film 4 contains a silicon oxide film. Unlike an organic film composed of so-called adhesives, the inorganic film 4 does not flow during bonding, so misalignment and tilt can be prevented. In addition, a film thickness of the inorganic film 4 is generally smaller than the wavelength of light; hence, even if there is a refractive index difference between the first base material 2 or the second base material 3 and the inorganic film 4, almost no light is reflected between them.

As illustrated in FIG. 2, the inorganic film 4 includes, for example, a first silicon oxide film 5 and a second silicon oxide film 6. The first silicon oxide film 5 is formed on a bonding surface 21 of the first base material 2 before bonding the first base material 2 and the second base material 3. On the other hand, the second silicon oxide film 6 is formed on a bonding surface 31 of the second base material 3 before bonding the first base material 2 and the second base material 3.

Note that when the second base material 3 is a quartz glass or quartz, the second silicon oxide film 6 may be absent. In this case, when the bonding surface of the quartz glass or the like is modified using the sequential plasma method, a higher bonding strength can be obtained compared with the case where the bonding surface of the quartz glass or the like is modified by only oxygen RIE.

The first base material 2 has the bonding surface 21 facing the second base material 3. The bonding surface 21 is a flat surface. Although the first base material 2 is plate-shaped in this embodiment, the first base material may be lens-shaped or prism-shaped as described later, and its shape is not particularly limited. The bonding surface 21 may be a flat surface. The first base material 2 has, for example, visible light transmittance. The visible light transmittance of the first base material 2 is, for example, 90% to 100%.

The first base material 2 is, for example, soda-lime glass, alkali-free glass, chemically strengthened glass, or lanthanum borate-based glass. Chemically strengthened glass is used for display cover glass, etc. Lanthanum borate-based glass is used for lenses, prisms, etc.

The first base material 2 is a glass with a SiO₂ content of 70 mol% or less. If a silicon oxide film is formed on the bonding surface 21 of the glass, the bonding strength can be improved by the sequential plasma method. The SiO₂ content of the glass is preferably 66 mol% or less, more preferably 60 mol% or less, and even more preferably 10 mol% or less. The SiO₂ content of the glass is 0 mol% or more.

The first base material 2 may be a glass with a total content of 5 mol% or more of Al₂O₃ and B₂O₃. From the results of experiments described later, it is assumed that the modification effect is not sufficiently obtained when the bonding surface modified by the sequential plasma method contains large amounts of Al₂O₃ and B₂O₃.

If the total content of Al₂O₃ and B₂O₃ of a glass is 5 mol% or more, the bonding strength can be improved by the sequential plasma method if a silicon oxide film is formed on the bonding surface 21 of the glass. The total content of Al₂O₃ and B₂O₃ is preferably 10 mol% or more, more preferably 15 mol% or more, and especially preferably 60 mol% or more. The total content of Al₂O₃ and B₂O₃ is preferably 70 mol% or less because of stabilization of the glass structure.

The Young’s modulus E₁ of the first base material 2 is, for example, 40 GPa to 200 GPa, and preferably 40 GPa to 150 GPa. If the Young’s modulus E₁ is 150 GPa or less, the bonding surface 21 of the first base material 2 is easily deformed to follow the minute unevenness of the bonding surface 31 of the second base material 3 during bonding, thereby preventing the generation of minute voids. The Young’s modulus E₁ is preferably 120 GPa or less.

The maximum thickness t₁ of the first base material 2 is, for example, 0.05 mm to 5 mm, and preferably 0.05 mm to 2.5 mm. The maximum thickness t₁ is measured in the direction perpendicular to the bonding surface 21. If the maximum thickness t₁ is 2.5 mm or less, the bonding surface 21 of the first base material 2 is easily deformed to follow the minute unevenness of the bonding surface 31 of the second base material 3 during bonding, thereby preventing the generation of minute voids. The maximum thickness t₁ is preferably 2 mm or less.

The product (E₁*t₁) of the Young’s modulus E₁ and the maximum thickness t₁ of the first base material 2 is, for example, 35 GPa·mm to 200 GPa·mm, preferably 35 GPa·mm to 180 GPa·mm, and more preferably 35 GPa·mm to 150 GPa·mm. If the product (E₁*t₁) is 150 GPa·mm or less, the bonding surface 21 of the first base material 2 is easily deformed to follow the minute unevenness of the bonding surface 31 of the second base material 3 during bonding, thereby preventing the generation of minute voids.

The surface roughness Ra of the bonding surface 21 of the first base material 2 is, for example, 0.01 nm to 1 nm. If the surface roughness Ra of the bonding surface 21 is 1 nm or less, the flatness of the bonding surface 21 is high, thereby preventing the generation of minute voids. The surface roughness Ra of the bonding surface 21 is preferably 0.5 nm or less. The surface roughness Ra is the “arithmetic mean roughness” described in the Japanese Industrial Standards JIS B 0601: 1994.

The mean linear expansion coefficient α1 of the first base material 2 at 50° C. to 200° C. is, for example, 0.1 ppm/°C to 20 ppm/°C, and preferably 0.5 ppm/°C to 10 ppm/°C. The mean linear expansion coefficient is measured in accordance with the Japanese Industrial Standard JIS R 3102: 1995.

The second base material 3 has a bonding surface 31 facing the first base material 2. The bonding surface 31 is a flat surface. Although the second base material 3 is plate-shaped in this embodiment, its shape is not particularly limited. It is sufficient that the bonding surface 31 is a flat surface. The second base material 3 has, for example, visible light transmittance. The visible light transmittance of the second base material 3 is, for example, 90% to 100%.

The second base material 3 is composed in the same manner as the first base material 2. The second base material 3 is, for example, soda-lime glass, alkali-free glass, chemically strengthened glass, or lanthanum borate-based glass. Chemically strengthened glass is used for cover glass of display, etc. Lanthanum borate-based glass is used for lenses, prisms, etc.

The second base material 3 is, for example, glass with a SiO₂ content of 70 mol% or less. If a silicon oxide film is formed on the bonding surface 31 of the glass, the bonding strength can be improved by the sequential plasma method. The SiO₂ content of the glass is preferably 66 mol% or less, more preferably 60 mol% or less, and even more preferably 10 mol% or less. The SiO₂ content of the glass is 0 mol% or more.

The second base material 3 may be a glass with a total content of 5 mol% or more of Al₂O₃ and B₂O₃. If a silicon oxide film is formed on the bonding surface 31 of the glass, the bonding strength can be improved by the sequential plasma method. The total content of Al₂O₃ and B₂O₃ is preferably 10 mol% or more, more preferably 15 mol% or more, and especially preferably 60 mol% or more. The total content of Al₂O₃ and B₂O₃ is preferably 70 mol% or less because of stabilization of the glass structure.

The second base material 3, unlike the first base material 2, is not limited to glass. The second base material 3 may be an inorganic single crystal or an inorganic polycrystal with a SiO₂ content of 70 mol% or less, for example, sapphire (aluminum oxide) or aluminum nitride. If a silicon oxide film is formed on these bonding surfaces 31, the bonding strength can be improved by the sequential plasma method.

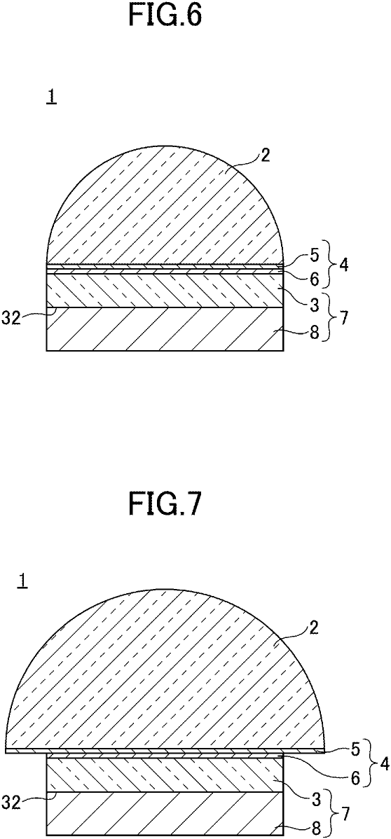

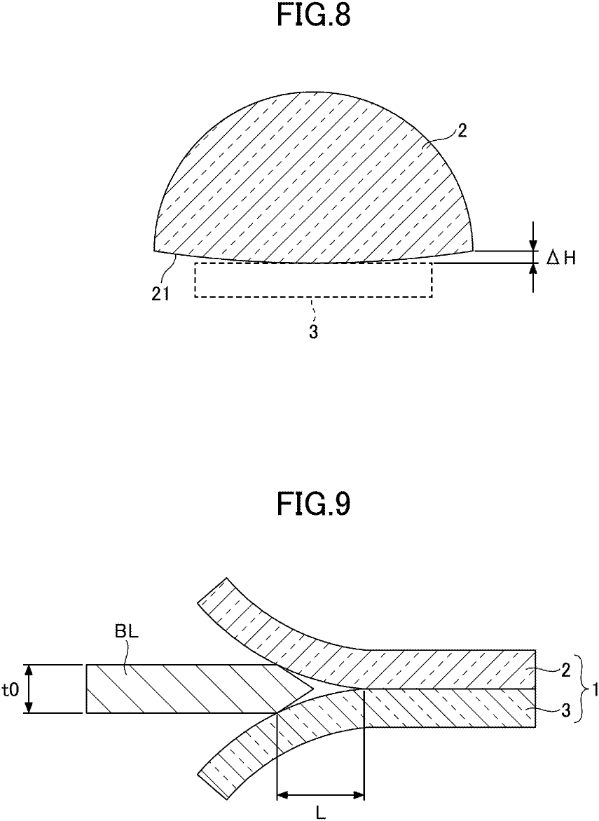

A sapphire substrate or an aluminum nitride substrate, which will be described in detail later, is used, for example, as a substrate for a light-emitting element 7, as illustrated in FIGS. 6 and 7. The light-emitting element 7 has the second base material 3 and a semiconductor layer 8 formed on a non-bonding surface 32 opposite to the bonding surface 31 of the second base material 3. The light-emitting element 7 may further have electrodes. The sapphire substrate or the aluminum nitride substrate may be used as a substrate for a semiconductor device other than the light-emitting element, such as a light-receiving device.

The second base material 3 may be resin. The resin may be, for example, PEN (polyethylene naphthalate), PET (polyethylene terephthalate), other polyester materials, PI (polyimide), COP (cycloolefin polymer), or PC (polycarbonate). If a silicon oxide film is formed on the bonding surface 31 of these resins, the bonding strength can be improved by the sequential plasma method.

The Young’s modulus E₂ of the second base material 3 is, for example, 40 GPa to 500 GPa, and preferably 40 GPa to 150 GPa. If the Young’s modulus E₂ is 150 GPa or less, the bonding surface 31 of the second base material 3 is easily deformed to follow the minute unevenness of the bonding surface 21 of the first base material 2 during bonding, thereby preventing the generation of minute voids. The Young’s modulus E₂ is preferably 120 GPa or less.

The maximum thickness t₂ of the second base material 3 is, for example, 0.05 mm to 5 mm, and preferably 0.05 mm to 2 mm. The maximum thickness t₂ is measured in the direction perpendicular to the bonding surface 31. If the maximum thickness t₂ is 2 mm or less, the bonding surface 31 of the second base material 3 is easily deformed to follow the minute unevenness of the bonding surface 21 of the first base material 2 during bonding, thereby preventing the generation of minute voids. The maximum thickness t₂ is preferably 1 mm or less.

The product (E₂*t₂) of the Young’s modulus E₂ and the maximum thickness t₂ of the second base material 3 is, for example, 35 GPa·mm to 200 GPa·mm. If the product (E₂*t₂) is 200 GPa·mm or less, the bonding surface 31 of the second base material 3 is easily deformed during bonding to follow the minute unevenness of the bonding surface 21 of the first base material 2, thereby preventing the generation of minute voids. The product (E₂*t₂) is preferably 150 GPa·mm or less, and more preferably 120 GPa·mm or less.

The sum (E₁*t₁+E₂*t₂) of the product (E₁*t₁) of the first base material 2 and the product (E2*t₂) of the second base material 3 is, for example, 70 GPa·mm to 300 GPa·mm. If the sum (E1*t₁+E₂*t₂) is 300 GPa·mm or less, the bonding surface 21 of the first base material 2 and the bonding surface 31 of the second base material 3 are easily deformed to follow each other’s minute unevenness during bonding, thereby preventing the generation of minute voids. The sum (E1*t₁+E₂*t₂) is preferably 270 GPa·mm or less.

The surface roughness Ra of the bonding surface 31 of the second base material 3 is, for example, 0.01 nm to 1 nm. If the surface roughness Ra of the bonding surface 31 is 1 nm or less, the flatness of the bonding surface 31 is high, thereby preventing the generation of minute voids. The surface roughness Ra of the bonding surface 31 is preferably 0.5 nm or less.

The mean linear expansion coefficient α2 of the second base material 3 at 50° C. to 200° C. is, for example, 0.1 ppm/°C to 20 ppm/°C, and preferably 0.5 ppm/°C to 10 ppm/°C. The difference (|α1-α2|) in the mean linear expansion coefficient between the first base material 2 and the second base material 3 at 50° C. to 200° C. is, for example, 0.0 ppm/°C to 4.0 ppm/°C. If the value of |α1-α2| is 4.0 ppm/°C or less, the thermal stress generated during annealing (step S7), which will be described later, can be reduced, and peeling at the bonding surface or destruction of the bonded body 1 can be prevented.

The first silicon oxide film 5 is formed on the bonding surface 21 of the first base material 2. The first silicon oxide film 5 is, for example, a SiO₂ film. The first silicon oxide film 5 is not limited to a silicon oxide film with a stoichiometric composition. That is, the first silicon oxide film 5 is not limited to a silicon oxide film with a silicon to oxygen molar ratio of 1:2.

The deposition method of the first silicon oxide film 5 is, for example, a sputtering method. The sputtering method may be a reactive sputtering method. The reactive sputtering method uses a metal target and a mixed gas of an inert gas such as a noble gas and a reactive gas (e.g., oxygen gas) to form a metal oxide on a target substrate. The sputtering method may use a metal oxide target.

The deposition method of the first silicon oxide film 5 is not limited to the sputtering method, but may be a plasma CVD (Chemical Vapor Deposition), vapor deposition, or ALD (Atomic Layer Deposition).

The film thickness of the first silicon oxide film 5 is, for example, 1 nm to 100 nm. If the film thickness of the first silicon oxide film 5 is 1 nm or more, the modification effect of the sequential plasma method can be obtained. On the other hand, if the film thickness of the first silicon oxide film 5 is 100 nm or less, the deterioration of the surface roughness Ra can be prevented.

The film thickness of the first silicon oxide film 5 is preferably 75 nm or less, more preferably 50 nm or less, still more preferably 30 nm or less, still further more preferably 20 nm or less, particularly preferably 10 nm or less, and still more particularly preferably 5 nm or less.

The surface roughness Ra of a bonding surface 51 of the first silicon oxide film 5 is, for example, 0.01 nm to 1 nm. If the surface roughness Ra of the bonding surface 51 is 1 nm or less, the flatness of the bonding surface 51 is high, thereby preventing the generation of minute voids. The surface roughness Ra of the bonding surface 51 is preferably 0.5 nm or less.

The second silicon oxide film 6 is formed on the bonding surface 31 of the second base material 3. The second silicon oxide film 6 is, for example, a SiO₂ film. The second silicon oxide film 6 is not limited to a silicon oxide film with a stoichiometric composition. That is, the second silicon oxide film 6 is not limited to a silicon oxide film with a silicon to oxygen molar ratio of 1:2. The deposition method of the second silicon oxide film 6 is the same as that of the first silicon oxide film 5.

The film thickness of the second silicon oxide film 6 is, for example, 1 nm to 100 nm. If the film thickness of the second silicon oxide film 6 is 1 nm or more, the modification effect of the sequential plasma method can be obtained. On the other hand, if the thickness of the second silicon oxide film 6 is 100 nm or less, deterioration of the surface roughness Ra can be prevented.

The film thickness of the second silicon oxide film 6 is preferably 75 nm or less, more preferably 50 nm or less, still more preferably 30 nm or less, still further more preferably 20 nm, particularly preferably 10 nm or less, and still more particularly preferably 5 nm or less.

The total thickness of the first silicon oxide film 5 and the second silicon oxide film 6 is 1 nm to 200 nm.

The surface roughness Ra of a bonding surface 61 of the second silicon oxide film 6 is, for example, 0.01 nm to 1 nm. If the surface roughness Ra of the bonding surface 61 is 1 nm or less, the flatness of the bonding surface 61 is high, thereby preventing the generation of minute voids. The surface roughness Ra of the bonding surface 61 is preferably 0.5 nm or less.

When the second base material 3 is quartz glass or quartz as described above, the second silicon oxide film 6 may be absent. In this case, if the bonding surface of quartz glass or the like is modified using the sequential plasma method, a higher bonding strength can be obtained compared with the case of modifying the bonding surface of quartz glass or the like using only oxygen RIE.

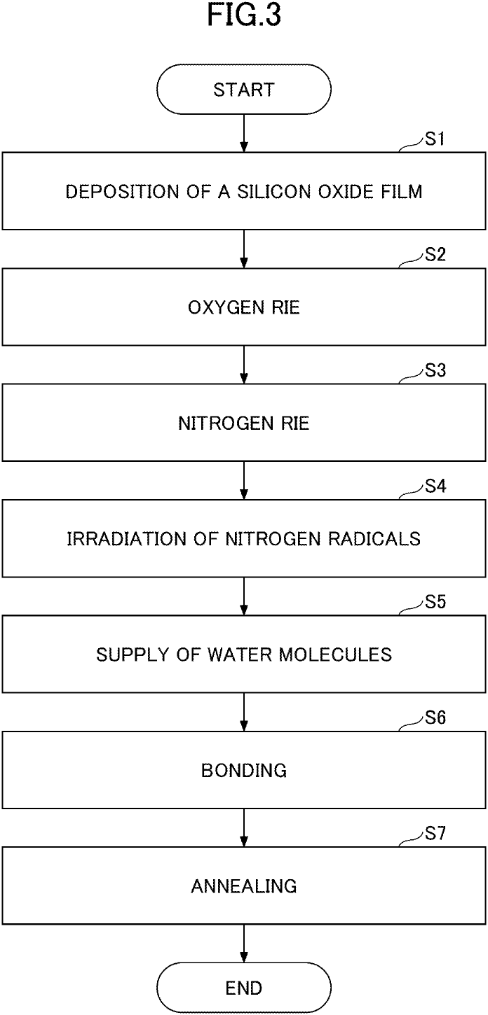

Next, a method of manufacturing the bonded body 1 is described with reference to FIG. 3. The method of manufacturing the bonded body 1 includes, for example, deposition of a silicon oxide film (step S1), oxygen RIE (step S2), nitrogen RIE (step S3), irradiation of nitrogen radicals (step S4), supply of water molecules (step S5), bonding (step S6), and annealing (step S7).

The method of manufacturing the bonded body 1 may include steps S1, S3 to S6, and may not include other steps S2 and S7. Moreover, the modification of the first silicon oxide film 5 (steps S2 to S5) and the modification of the second silicon oxide film 6 (steps S2 to S5) need not be carried out at the same time, but may be carried out sequentially.

Step S1 includes forming a first silicon oxide film 5 on the bonding surface 21 of the first base material 2. Step S1 also includes forming a second silicon oxide film 6 on the bonding surface 31 of the second base material 3. The first silicon oxide film 5 and the second silicon oxide film 6 need not be formed at the same time, and may be formed sequentially. The film formation method is the sputtering method or the like as described above.

Step S2 includes applying oxygen RIE to the bonding surface 51 of the first silicon oxide film 5. Step S2 also includes applying oxygen RIE to the bonding surface 61 of the second silicon oxide film 6. The oxygen RIE includes, for example, holding the base material on the stage in the treatment vessel, discharging residual gas in the treatment vessel, introducing oxygen gas into the treatment vessel, and applying a radiofrequency bias to the base material held on the stage. The frequency of the radiofrequency bias is, for example, 13.56 MHz. The application of the radiofrequency bias generates a sheath region near the bonding surface of the silicon oxide film. The sheath region is a region where oxygen ions repeatedly collide with the bonding surface of the silicon oxide film. The collision of oxygen ions etches the bonding surface of the silicon oxide film. A mixture of an oxygen gas and a noble gas may be introduced into the treatment vessel.

Step S3 includes applying nitrogen RIE to the bonding surface 51 of the first silicon oxide film 5. Step S3 also includes applying nitrogen RIE to the bonding surface 61 of the second silicon oxide film 6. Nitrogen RIE includes, for example, holding the base material on the stage in the treatment vessel, discharging residual gas in the treatment vessel, introducing nitrogen gas into the treatment vessel, and applying a radiofrequency bias to the base material held on the stage. The frequency of the radiofrequency bias is, for example, 13.56 MHz. By applying the radiofrequency bias, a sheath region is generated near the bonding surface of the silicon oxide film. The sheath region is a region where nitrogen ions repeatedly collide with the bonding surface of the silicon oxide film. The collision of nitrogen ions etches the bonding surface of the silicon oxide film. A mixture of a nitrogen gas and a noble gas may be introduced into the treatment vessel.

Step S4 includes irradiating the bonding surface 51 of the first silicon oxide film 5 with nitrogen radicals. Step S4 also includes irradiating the bonding surface 61 of the second silicon oxide film 6 with nitrogen radicals. The irradiation of nitrogen radicals includes, for example, holding the base material on the stage in the treatment vessel, discharging residual gas in the treatment vessel, introducing nitrogen gas into the treatment vessel, and plasmizing the nitrogen gas by microwave or the like. The frequency of the microwave is, for example, 2.45 GHz. The plasma is not limited to microwave plasma, but may be capacitively coupled plasma, inductively coupled plasma, etc. Nitrogen radicals may be generated. The irradiation of nitrogen radicals forms sites to which OH groups are attached. The sites to which OH groups are attached are also formed by oxygen RIE and nitrogen RIE.

Step S5 includes supplying water molecules to the bonding surface 51 of the first silicon oxide film 5. Step S5 also includes supplying water molecules to the bonding surface 61 of the second silicon oxide film 6. The supply of water molecules includes, for example, removing the base material from the treatment vessel and exposing the removed base material to the atmosphere. With the water molecules in the atmosphere, OH groups are formed at the bonding surface of the silicon oxide film. The supply of water molecules may be carried out inside the treatment vessel. For example, water molecules can be supplied by introducing steam gas into the treatment vessel. The water molecules can be either gas or liquid.

Step S6 includes bonding the first base material 2 and the second base material 3 to obtain the bonded body 1. The bonding of the first base material 2 and the second base material 3 may be performed under atmospheric pressure or under reduced atmospheric pressure. It is preferable that the bonding is performed under reduced atmospheric pressure to prevent the formation of voids. Since OH groups are formed in advance on the bonding surface 51 of the first silicon oxide film 5 and the bonding surface 61 of the second silicon oxide film 6, hydrogen bonding between the OH groups occurs and high bonding strength is obtained. Step S6 may involve pressing the first base material 2 and the second base material 3 together.

Step S7 includes heating and annealing the bonding 1. The hydrogen bond turns into a covalent bond, resulting in a higher bonding strength. The heating temperature of the bonded body 1 is, for example, 120 to 200° C. The heating time of the bonded body 1 is, for example, 10 minutes to 7 hours. Annealing can not only improve the bonding strength but also increase a contact area between the bonding surfaces and reduce voids.

The bonding strength of the bonded body 1 is measured by the crack opening method illustrated in FIG. 9. The inorganic film 4 is not illustrated in FIG. 9. In the crack opening method, a razor blade-like blade BL is inserted from the outside into the bonding interface between the first base material 2 and the second base material 3 bonded to each other, and the peeling length L is measured. The shorter the peeling length L, the higher the bonding strength. When the bonding strength is sufficiently high, the insertion of the blade BL destructs the first base material 2 or the second base material 3.

When calculating the bonding strength _{Υ} from the peeling length L, the following equation (1) is used.

$$\text{γ+=} \frac{3 {t}_{0}^{2} {E}_{1} {t}_{1}^{3} {E}_{2} {t}_{2}^{3}}{16 {L}^{4} \left({E}_{1} {t}_{1}^{3} + {E}_{2} {t}_{2}^{3}\right)} \qquad \text{[Equation 1]}$$

In equation (1), E₁, E₂, t₁ and t₂ are as illustrated above, and t₀ is the thickness of the blade BL. The unit of the bonding strength _{Υ} is J/m².

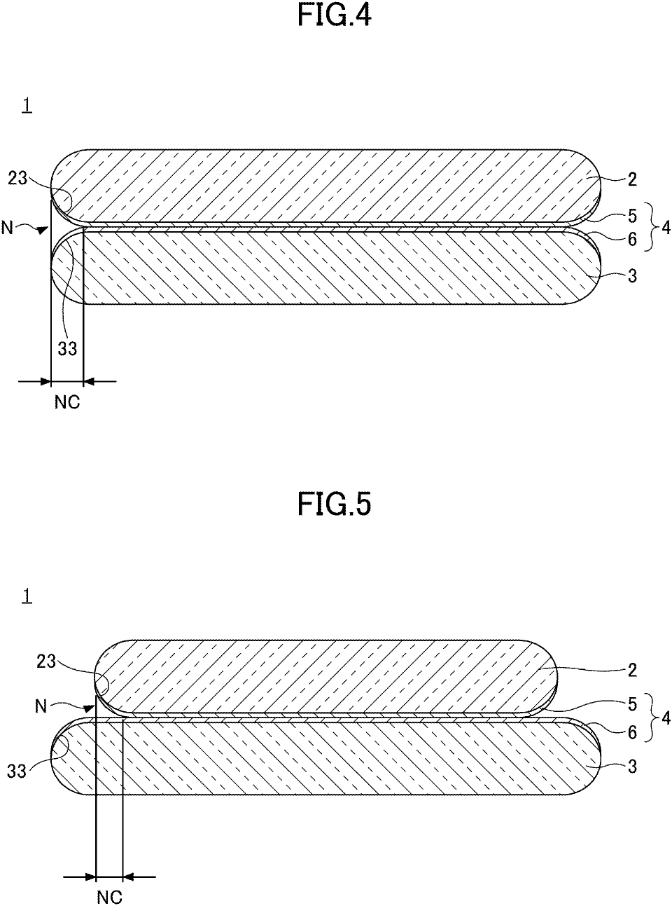

Next, with reference to FIG. 4, a bonded body 1 according to a first modification will be described. The bonded body 1 of this modification has a wedge-shaped groove N on an outer edge of a bonding interface between the first base material 2 and the second base material 3 (more specifically, the bonding interface between the first silicon oxide film 5 and the second silicon oxide film 6). The groove N is formed over the entire outer edge of the bonding interface, but may be formed only on a part of the outer edge of the bonding interface.

If the groove N is present, a blade such as a razor blade can be inserted into the groove N after bonding (step S6) and before annealing (step S7) so that the first base material 2 and the second base material 3 can be peeled off, and the first base material 2 and the second base material 3 can be reattached. Reattaching is performed before annealing in order to prevent the destruction of the base materials.

In plan view, the first base material 2 and the second base material 3 have similar dimensions and have contours that overlap each other. In this case, the groove N is formed between an edge-removed surface 23 of the first base material 2 and an edge-removed surface 33 of the second base material 3. The edge-removed surfaces 23 and 33 are rounded surfaces in FIG. 4, but may be chamfered surfaces. The edge-removed surface may be formed only on one of the first base material 2 and the second base material 3. It is sufficient to form a groove N.

The depth NC of the groove N is measured in a direction perpendicular to the outer edge of the first base material 2, and the like, in plan view. The depth NC is, for example, 0.05 mm to 0.5 mm, preferably 0.1 mm to 0.3 mm. If the depth NC is 0.05 mm or more, blade insertion is easy. If the depth NC is 0.5 mm or less, crack generation starting from the groove N can be prevented.

Next, with reference to FIG. 5, a bonded body 1 according to a second modification will be described. The bonded body 1 of this modification has a wedge-shaped groove N as in the first modification. In the bonded body 1 of this modification, unlike the first modification, the first base material 2 is smaller than the second base material 3 in plan view, and the contour of the first base material 2 is inside the contour of the second base material 3.

The reference point (the point where NC = 0) of the depth NC of the groove N is the outer edge of the first base material 2. The depth NC is, for example, 0.05 mm to 0.5 mm, preferably 0.1 mm to 0.3 mm. If the depth NC is 0.05 mm or more, blade insertion is easy. If the depth NC is 0.5 mm or less, crack generation starting from the groove N can be prevented.

In this modification, the first base material 2 is smaller than the second base material 3 in plan view and the contour of the first base material 2 is inside the contour of the second base material 3; however, the second base material 3 may be smaller than the first base material 2 in plan view and the contour of the second base material 3 may be inside the contour of the first base material 2. In the latter case, the reference point of the depth NC of the groove N (the point where NC = 0) is the outer edge of the second base material 3.

Next, with reference to FIG. 6, a bonded body 1 according to a third modification will be described. In the bonded body 1 of this modification, the first base material 2 is a lens. The first base material 2 is, for example, a spherical lens having a convex surface opposite to the bonding surface of the first base material 2. The light emitted by a light-emitting element 7 described later is taken out to the outside through the lens.

A light-emitting surface of the lens is curved to reduce total reflection. The lens is, for example, a plano-convex lens. The lens can be a spherical or aspherical lens, but a spherical lens is preferable for a light extraction efficiency.

When the lens is attached to the light-emitting element 7, the light extraction efficiency is improved by two to three times. The use of the lens is not particularly limited. The lens may be a plano-concave lens according to its use.

The light-emitting element 7 is formed before bonding of the first base material 2 and the second base material 3. A substrate of the light-emitting element 7 corresponds to the second base material 3. As the second base material 3, a sapphire substrate (aluminum oxide substrate) or an aluminum nitride substrate is used. The light-emitting element 7 is, for example, an ultraviolet light-emitting element. The ultraviolet light may be either UVC (wavelength 200 nm to 280 nm), UVB (wavelength 280 nm to 315 nm), and UVA (wavelength 315 nm to 400 nm). The light-emitting element 7 may be a visible light-emitting element or an infrared light-emitting element.

Since the thickness of the inorganic film 4 can be smaller than the length of the wavelength of light emitted by the light-emitting element 7, the total reflection generated at an interface between the second base material 3 and the inorganic film 4 can be reduced, and the light efficiently transmits from the second base material 3 to the first base material 2 through the inorganic film 4. Therefore, if the first base material 2 and the second base material 3 are bonded using the inorganic film 4, the light emitted by the light-emitting element 7 is taken out through the inorganic film 4 and the first base material 2 to the outside of the light-emitting element 7, and the light extraction efficiency of the light-emitting element 7 can be greatly improved.

On the other hand, if the first base material 2 and the second base material 3 are bonded using an organic film made of a resin adhesive, the thickness of the organic film becomes greater than the length of the wavelength of the light emitted from the light-emitting element 7, so that total reflection at the interface between the second base material 3 and the organic film cannot be reduced, and the light extraction efficiency becomes low. Therefore, using the inorganic film 4 for bonding the first base material 2 and the second base material 3 can improve the light extraction efficiency compared to using the organic film, and the light output of the light-emitting element 7 can be greatly improved.

Next, with reference to FIG. 7, a bonded body 1 according to a fourth modification will be described. In the above third modification, the first base material 2 and the second base material 3 have similar sizes and have overlapping contours in plan view. In contrast, in this modification, the first base material 2 is larger than the second base material 3 and protrudes outside the second base material 3 in plan view.

By holding a protruding portion of the first base material 2, the first base material 2 and the second base material 3 can be peeled off, and the first base material 2 and the second base material 3 can be reattached. The reattaching is performed before annealing in order to prevent destruction of the base materials. In plan view, it is sufficient that 30% or more of the outer edge of the first base material 2 protrudes outside the second base material 3.

FIG. 8 illustrates an example of a state of a lens, which is the first base material 2, before bonding. The lens, which is the first base material 2, is also referred to as the lens 2. Before bonding the lens 2 to the second base material 3, the bonding surface 21 of the lens 2 facing the second base material 3 may be a convex curved surface. The convex curved surface is a dome-shaped curved surface whose center protrudes more than the periphery. The maximum height difference ΔH of the bonding surface 21 is, for example, 5 nm to 400 nm. The ΔH is measured, for example, by a white interferometer, except for a region within 400 µm from the outer edge of the bonding interface 21.

If the ΔH is 5 nm or more, the stress can be concentrated at the center of the bonding surface 21, the bonding can proceed with a small load, and the breakage of the light-emitting element 7 can be prevented. On the other hand, if the ΔH is 400 nm or less, the adhesion at the bonding interface is good after the bonding of the lens 2 and the second base material 3. The ΔH is preferably 10 nm to 300 nm and more preferably 15 nm to 250 nm.

As illustrated in FIG. 10, before bonding the lens 2 to the second base material 3, a part of the bonding surface 21 of the lens 2 may be a convex curved surface. Of the bonding surface 21, a region 21a overlapping the second base material 3 in plan view after bonding may be a convex curved surface. The region not overlapping the second base material 3 may be flat. The maximum height difference ΔHA of the region 21a is, for example, 5 nm to 200 nm. The ΔHA is measured, for example, with a white interferometer.

If the ΔHA is 5 nm or more, the stress can be concentrated at the center of the bonding surface 21, the bonding can proceed with a small load, and the breakage of the light-emitting element 7 can be prevented. On the other hand, if the ΔHA is 200 nm or less, the adhesion at the bonding interface is good after the bonding of the lens 2 and the second base material 3. The ΔHA is preferably 10 nm to 150 nm and more preferably 15 nm to 100 nm.

It is also preferable that the maximum height difference ΔHA of a part of the region 21a of the bonding surface 21 is 5 nm to 200 nm even when the whole of the bonding surface 21 is a convex curved surface as illustrated in FIG. 8. Since the region 21a is a part of the bonding surface 21, the maximum height difference ΔHA of the region 21a is smaller than the maximum height difference ΔH of the bonding surface 21.

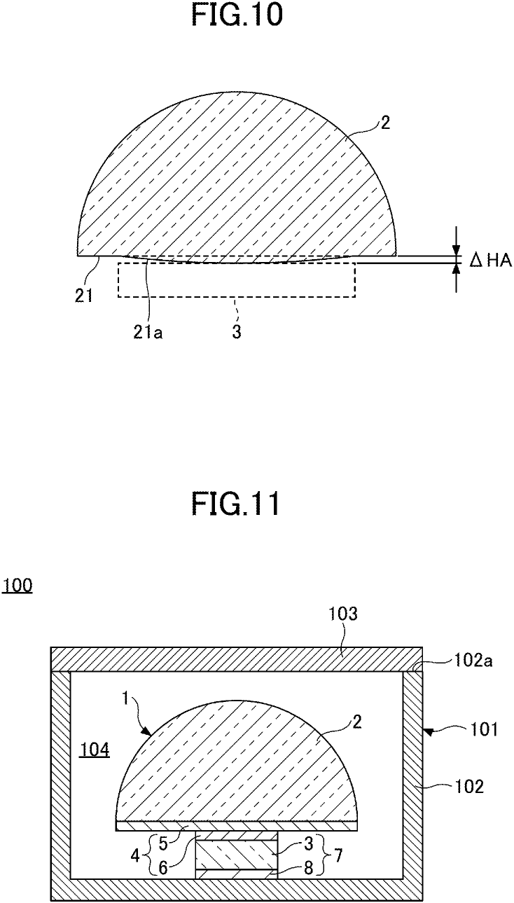

As illustrated in FIG. 11 to FIG. 13, a light-emitting device 100 includes a bonded body 1 and a container 101 configured to house the bonded body 1. The bonded body 1 has a lens 2 and a light-emitting element 7. A prism or the like may be used instead of the lens 2, and the bonded body 1 may have an optical member and a light-emitting element 7. The light-emitting element 7 is, for example, an ultraviolet light-emitting element. The light-emitting element 7 has a second base material 3 and a semiconductor layer 8. The second base material 3 is, for example, a sapphire substrate or an aluminum nitride substrate. The semiconductor layer 8 is formed on a non-bonding surface opposite to the bonding surface of the second base material 3 bonded to the lens 2.

The container 101 includes a substrate 102 and a cover 103, for example, as illustrated in FIG. 11. On the surface 102a of the substrate 102, a trough 104 is formed to accommodate the bonding 1. The light-emitting element 7 is fixed to the inner bottom surface of the trough 104. The light-emitting element 7 is fixed by a known method such as die bonding. After the light-emitting element 7 and the lens 2 are bonded, the light-emitting element 7 is fixed to the substrate 102, but the order may be reversed; the light-emitting element 7 and the lens 2 may be bonded after the light-emitting element 7 is fixed to the substrate 102.

The bonded body 1 is fixed with the lens 2 facing the cover 103. The cover 103 is made of a material that transmits light emitted from the light-emitting element 7. The light emitted from the light-emitting element 7 passes through the lens 2 and the cover 103 in this order. The cover 103 is flat and bonded to the surface 102a of the substrate 102.

The cover 103 is made of a material that transmits light emitted from the light-emitting element 7. Such materials include, for example, quartz or inorganic glass. The cover 103 and the substrate 102 are bonded with metal solder, inorganic adhesive or organic adhesive. The adhesion prevents entry of moisture or the like from the outside world, thereby preventing the performance degradation of the light-emitting element 7.

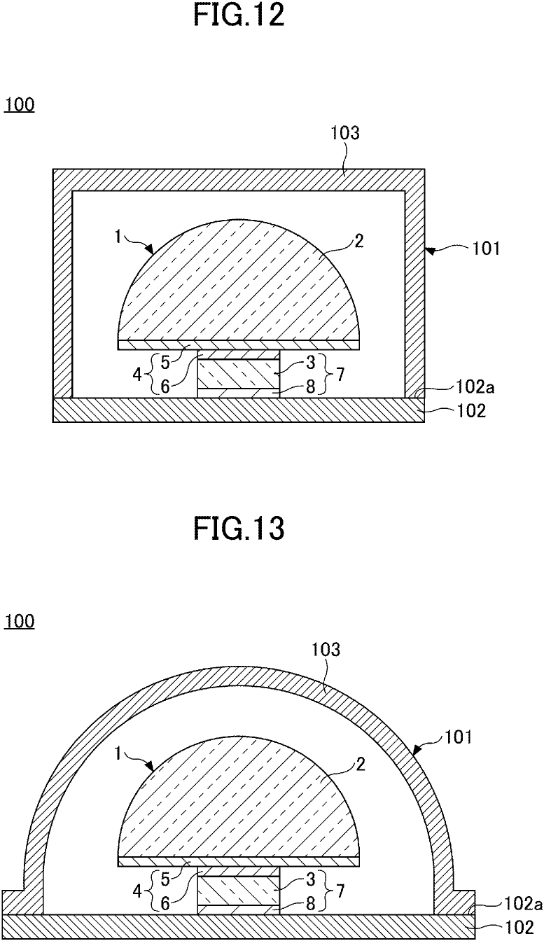

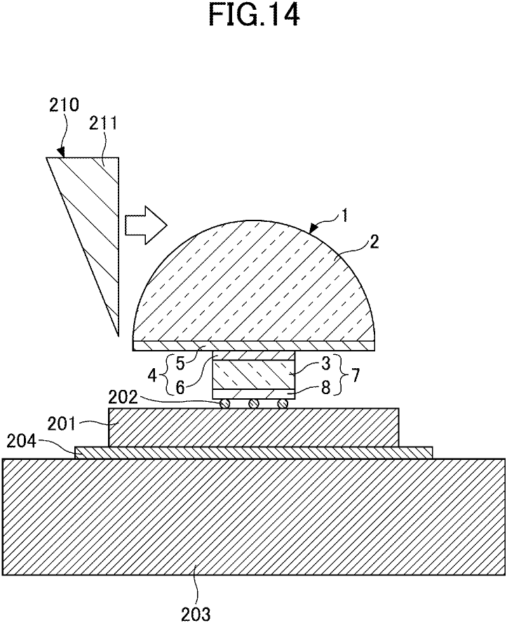

The cover 103 is flat as illustrated in FIG. 11, but may be box-shaped as illustrated in FIG. 12 or dome-shaped as illustrated in FIG. 13. When the cover 103 is box-shaped or dome-shaped, the light emitted radially from the lens 2 can be efficiently taken outside. When the cover is dome-shaped, the light extraction efficiency is particularly high. Also, when the cover 103 is box-shaped or dome-shaped, the trough 104 is not formed on the surface 102a of the substrate 102, so that the cost of the substrate 102 can be reduced.

### EXAMPLES

The experimental data are described below. First, compositions of the four types of glasses A to D used in the experiment are illustrated in Table 1.

TABLE 1

| COMPOSITION [mol%] | | GLASS A | GLASS B | GLASS C | GLASS D |
|---|---|---|---|---|---|
| TYPICAL ELEMENT | SiO₂ | 65.11 | 64.27 | 66.82 | 5.83 |
| | B₂O₃ | 7.50 | | 6.18 | 66.59 |
| | Al₂O₃ | 10.87 | 7.98 | 7.73 | |
| ALKALI METALS | Na₂O | | 12.48 | | |
| | K₂O | | 3.99 | | |
| ALKALI EARTH METALS | MgO | 4.86 | 10.48 | 3.56 | |
| | CaO | 4.65 | 0.10 | 3.83 | |
| | SrO | 5.04 | 0.10 | 4.85 | |
| | BaO | 0.00 | 0.10 | 7.03 | |
| TRANSITION METALS | Fe₂O₃ | 0.29 | | | |
| | ZrO₂ | | 0.50 | | |
| RARE-EARTH METALS | La₂O₃ | | | | 19.29 |
| | Y₂O₃ | | | | 8.29 |
| NON-METALS | SO₃ | 0.29 | | | |
| | F | 0.48 | | | |
| | Cl | 0.92 | | | |

Glass A is alkali-free glass. Glass B is alkali metal oxide-containing glass. Glass C is alkali-free glass. Glass D is lanthanum borate-based glass. The glasses A to D all have a SiO₂ content of 70 mol% or less.

In Examples 1 to 15 below, glass-to-glass or glass-to-ceramic bonding was performed using the glasses A to D described in Table 1. The bonding conditions and evaluation results are illustrated in Tables 2 to 4. Examples 1 to 7 and 13 to 14 below are examples, and Examples 8 to 12 and 15 below are comparative examples. In Example 16, bonding of quartz glass (SiO₂ content: 100 mol%) and ceramics was performed. The bonding conditions and evaluation results are illustrated in Table 4. Example 16 is a reference example.

TABLE 2

| | | EXAMPLE 1 | EXAMPLE 2 | EXAMPLE 3 | EXAMPLE 4 | EXAMPLE 5 | EXAMPLE 6 |
|---|---|---|---|---|---|---|---|
| FIRST SUBSTRATE | MATERIAL | GLASS A | GLASS A | GLASS B | GLASS C | GLASS C | GLASS C |
| | PLAN VIEW SHAPE | CIRCULAR | CIRCULAR | CIRCULAR | CIRCULAR | CIRCULAR | CIRCULAR |
| | DIAMETER OR LENGTH OF A PIECE [mm] | 100 | 100 | 100 | 100 | 100 | 100 |
| | YOUNG’ S MODULUS E1 [GPa] | 77 | 77 | 73 | 75 | 75 | 75 |
| | THICKNESS t1 [mm] | 0.5 | 0.5 | 0.5 | 0.5 | 0.5 | 0.5 |
| | E1 × t1 [GΡa▪mm] | 38.5 | 38.5 | 36.5 | 37.5 | 37.5 | 37.5 |
| | α 1 [ppm/°C] | 3.7 | 3.7 | 8.2 | 4.8 | 4.8 | 4.8 |
| | SURFACE ROUGHNESS Ra [nm] | 0.15 | 0.15 | 0.26 | 0.17 | 0.17 | 0.17 |
| FIRST BONDING FILM | MATERIAL | SiO₂ | SiO₂ | SiO₂ | SiO₂ | SiO₂ | SiO₂ |
| | FILM THICKNESS [nm] | 5 | 5 | 5 | 5 | 5 | 5 |
| | SURFACE ROUGHNESS Ra [nm] | 0.17 | 0.17 | 0.29 | 0.18 | 0.18 | 0.18 |
| SECOND SUBSTRATE | MATERIAL | GLASS A | GLASS A | GLASS B | GLASS C | GLASS C | sapphire |
| | PLAN VIEW SHAPE | CIRCULAR | CIRCULAR | CIRCULAR | CIRCULAR | CIRCULAR | CIRCULAR |
| | DIAMETER OR LENGTH OF A PIECE [mm] | 100 | 100 | 100 | 100 | 100 | 50 |
| | YOUNG’ S MODULUS E2 [GPa] | 77 | 77 | 73 | 75 | 75 | 470 |
| | THICKNESS t2 [mm] | 0.5 | 0.5 | 0.5 | 0.5 | 0.5 | 0.3 |
| | E2 × t2 [GPa▪mm] | 38.5 | 38.5 | 36.5 | 37.5 | 37.5 | 141 |
| | α 2 [ppm/°C] | 3.7 | 3.7 | 8.2 | 4.8 | 4.8 | 6.9 |
| | SURFACE ROUGHNESS Ra [nm] | 0.15 | 0.15 | 0.26 | 0.17 | 0.17 | 0.09 |
| SECOND BONDING FILM | MATERIAL | SiO₂ | SiO₂ | SiO₂ | SiO₂ | SiO₂ | SiO₂ |
| | FILM THICKNESS [nm] | 5 | 5 | 5 | 5 | 5 | 5 |
| | SURFACE ROUGHNESS Ra[nm] | 0.17 | 0.17 | 0.29 | 0.18 | 0.18 | 0.19 |
| E1 × t1+E2 × t2 [GPa▪mm] | | 77 | 77 | 73 | 75 | 75 | 178.5 |
| \|α 1- α 2\| [ppm/°C] | | 0.0 | 0.0 | 0.0 | 0.0 | 0.0 | 2.1 |
| PRESENCE OR ABSENCE OF CUTOUT | | YES | NO | YES | YES | YES | YES |
| BEFORE ANNEALING | | YES | NO | YES | YES | YES | YES |
| PEELING DURING ANNEALING | | NO | NO | NO | NO | NO | NO |
| BONDING STRENGTH [J/m²] | | DESTRUCTION | DESTRUCTION | DESTRUCTION | DESTRUCTION | DESTRUCTION | DESTRUCTION |
| N CONCENTRATION OF SiO₂ FILM [at%] | | 1.8 | 1.7 | 1.7 | 1.9 | 2.0 | 2.0 |

TABLE 3

| | | EXAMPLE 7 | EXAMPLE 8 | EXAMPLE 9 | EXAMPLE 10 | EXAMPLE 11 | EXAMPLE 12 |
|---|---|---|---|---|---|---|---|
| FIRST SUBSTRATE | MATERIAL | GLASS D | GLASS A | GLASS B | GLASS A | GLASS C | GLASS D |
| | PLAN VIEW SHAPE | SQUARE | CIRCULAR | CIRCULAR | CIRCULAR | CIRCULAR | SQUARE |
| | DIAMETER OR LENGTH OF A PIECE [mm] | 50 | 100 | 100 | 100 | 100 | 50 |
| | YOUNG’ S MODULUS E1 [GPa] | 111 | 77 | 73 | 77 | 75 | 111 |
| | THICKNESS t1 [mm] | 1.0 | 0.5 | 0.5 | 0.5 | 0.5 | 1.0 |
| | E1 × t1 [GΡa▪mm] | 111 | 38.5 | 36.5 | 38.5 | 37.5 | 111 |
| | α 1 [ppm/°C] | 7.4 | 3.7 | 8.2 | 3.7 | 4.8 | 5.8 |
| | SURFACE ROUGHNESS Ra [nm] | 0.47 | 0.15 | 0.26 | 0.15 | 0.17 | 0.47 |
| FIRST BONDING FILM | MATERIAL | SiO₂ | - | - | Al₂O₃ | - | - |
| | FILM THICKNESS [nm] | 5 | - | - | 5 | - | - |
| | SURFACE ROUGHNESS Ra [nm] | 0.23 | - | - | 0.17 | - | - |
| SECOND SUBSTRATE | MATERIAL | sapphire | GLASS A | GLASS B | GLASS A | sapphire | sapphire |
| | PLAN VIEW SHAPE | CIRCULAR | CIRCULAR | CIRCULAR | CIRCULAR | CIRCULAR | CIRCULAR |
| | DIAMETER OR LENGTH OF A PIECE [mm] | 50 | 100 | 100 | 100 | 50 | 50 |
| | YOUNG’ S MODULUS E2 [GPa] | 470 | 77 | 73 | 77 | 470 | 470 |
| | THICKNESS t2 [mm] | 0.3 | 0.5 | 0.5 | 0.5 | 0.3 | 0.3 |
| | E2 × t2 [GPa▪mm] | 141 | 38.5 | 36.5 | 38.5 | 141 | 141 |
| | α 2 [ppm/°C] | 6.9 | 3.7 | 8.2 | 3.7 | 6.9 | 6.9 |
| | SURFACE ROUGHNESS Ra [nm] | 0.09 | 0.15 | 0.26 | 0.15 | 0.09 | 0.09 |
| SECOND BONDING FILM | MATERIAL | SiO₂ | - | - | Al₂O₃ | - | - |
| | FILM THICKNESS [nm] | 5 | - | - | 5 | - | - |
| | SURFACE ROUGHNESS Ra [nm] | 0.19 | - | - | 0.17 | - | - |
| E1 × t1+E2 × t2 [GPa▪mm] | | 252 | 77 | 73 | 77 | 178.5 | 252 |
| \|α1-α2\| [ppm/°C] | | 0.5 | 0.0 | 0.0 | 0.0 | 2.1 | 1.1 |
| PRESENCE OR ABSENCE OF CUTOUT | | - | YES | YES | YES | YES | - |
| BEFORE ANNEALING | | YES | YES | YES | YES | YES | YES |
| PEELING DURING ANNEALING | | NO | NO | NO | NO | NO | NO |
| BONDING STRENGTH [J/m²] | | 1.2 | 0.9 | 0.7 | 0.4 | 0.7 | 0.8 |
| N CONCENTRATION OF SiO₂ FILM [at%] | | 1.7 | | | | | |

TABLE 4

| | | EXAMPLE 13 | EXAMPLE 14 | EXAMPLE 15 | EXAMPLE 16 |
|---|---|---|---|---|---|
| FIRST SUBSTRATE | MATERIAL | GLASS A | GLASS D | GLASS D | QUARTZ GLASS |
| | PLAN VIEW SHAPE | CIRCULAR | CIRCULAR | CIRCULAR | CIRCULAR |
| | DIAMETER OR LENGTH OF A PIECE [mm] | 100 | 3 | 3 | 50 |
| | YOUNG’ S MODULUS E1 [GPa] | 77 | 111 | 111 | 74 |
| | THICKNESS t1 [mm] | 0.5 | 1.5 | 1.5 | 0.5 |
| | E1 × t1 [GPa▪mm] | 38.5 | 167 | 167 | 37 |
| | α 1 [ppm/°C] | 3.7 | 5.8 | 5.8 | 0.5 |
| | SURFACE ROUGHNESS Ra [nm] | 0.15 | 0.4 | 0.4 | 0.15 |
| FIRST BONDING FILM | MATERIAL | SiO₂ | SiO₂ | - | - |
| | FILM THICKNESS [nm] | 5 | 5 | - | - |
| | SURFACE ROUGHNESS Ra [nm] | 0.17 | 0.17 | - | - |
| SECOND SUBSTRATE | MATERIAL | GLASS A | sapphire (LED) | sapphire (LED) | sapphire |
| | PLAN VIEW SHAPE | CIRCULAR | SQUARE | SQUARE | CIRCULAR |
| | DIAMETER OR LENGTH OF A PIECE [mm] | 100 | 1 | 1 | 50 |
| | YOUNG’ S MODULUS E2 [GPa] | 77 | 470 | 470 | 470 |
| | THICKNESS t2 [mm] | 0.5 | 0.4 | 0.4 | 0.3 |
| | E2 × t2 [GPa▪mm] | 38.5 | 188 | 188 | 141 |
| | α 2 [ppm/°C] | 3.7 | 6.9 | 6.9 | 6.9 |
| | SURFACE ROUGHNESS Ra [nm] | 0.15 | 0.80 | 0.80 | 0.09 |
| SECOND BONDING FILM | MATERIAL | SiO₂ | SiO₂ | - | SiO₂ |
| | FILM THICKNESS [nm] | 5 | 5 | - | 5 |
| | SURFACE ROUGHNESS Ra [nm] | 0.17 | 0.17 | - | 0.17 |
| E1 × t1+E2 × t2 [GPa▪mm] | | 77 | 355 | 355 | 178 |
| \|α1 - α2\| [ppm/°C] | | 0.0 | 1.1 | 1.1 | 6.4 |
| PRESENCE OR ABSENCE OF CUTOUT | | YES | - | - | - |
| BEFORE ANNEALING | | YES | YES | YES | - |
| PEELING DURING ANNEALING | | NO | NO | NO | YES |
| BONDING STRENGTH [J/m²] | | 1.0 | | | - |
| SECOND BONDING STRENGTH [kgw] | | | 2 OR MORE | 0.5 | - |
| N CONCENTRATION OF SiO₂ FILM [at%] | | NO DETECTION | 1.7 | | - |
| Δ H [nm] | | | 20 | 20 | - |

In Tables 2 to 4, the first bonding film is an inorganic film formed on the bonding surface of the first base material before bonding the first and second base materials. Similarly, the second bonding film is an inorganic film formed on the bonding surface of the second base material before bonding the first and second base materials. The bonding conditions and evaluation results for Examples 1 to 15 are described in detail below.

In Example 1, a glass substrate consisting of glass A was prepared as first and second base materials. On the bonding surfaces of the glass substrates, a SiO₂ film was formed by a reactive sputtering method. Metallic silicon was used as a target of the reactive sputtering method. The bonding surfaces of the SiO₂ films were modified by a sequential plasma method. Specifically, the bonding surfaces of the SiO₂ films were modified by performing oxygen RIE, nitrogen RIE, and irradiation of nitrogen radicals in this order, and then exposed to the atmosphere to attach OH groups. The treatment time of oxygen RIE was 180 seconds, the treatment time of nitrogen RIE was 180 seconds, and the irradiation time of nitrogen radical was 15 seconds. Then, the two glass substrates were bonded through the two modified SiO₂ films. A wedge-like groove was formed on an outer edge of the bonding interface. The groove was formed between the edge-removed surfaces. The depth of the groove was 0.28 mm. When a razor blade was inserted into the groove, the two glass substrates were peeled off. Then, the two glass substrates that had been peeled off were bonded again, and the resulting bonded body was annealed at 200° C. for 2 hours. The bonding strength after annealing was measured by the crack opening method. As a result, the glass substrate broke and the bonding strength was sufficiently high. In Example 1, the nitrogen concentration of the two SiO₂ films bonded to each other was measured by energy dispersive X-ray analysis, and the nitrogen concentration of the SiO₂ films was 1.8 atom%.

The nitrogen concentration in the SiO₂ films after bonding was measured by performing energy dispersive X-ray analysis using a scanning transmission electron microscope. The bonded body was cut in a plane perpendicular to the bonding interface, the cross section was exposed, and the bonded body was thinned by polishing with an appropriate technique. For the thinned bonded body, a rectangular region including the SiO₂ films at the bonding interface was elementally mapped by energy dispersive X-ray analysis using a scanning transmission electron microscope. One-dimensional nitrogen concentration profiles were obtained in the direction perpendicular to the bonding interface by integrating the mapped data in the direction parallel to the bonding interface. Examples of observation conditions include, but are not limited to, an acceleration voltage of 200 kV, a field of view magnification of 600,000 times, and a field of view resolution of 192 pixels by 256 pixels. In this specification, the nitrogen concentration of the SiO₂ films is the peak value of the nitrogen concentration profile of the SiO₂ film.

In Example 2, two glass substrates were bonded under the same bonding conditions as in Example 1 except that a glass substrate without an edge-removed surface was used as the first and second substrates. A wedge-like groove was not formed on the outer edge of the bonding interface, and the two glass substrates were not peeled off. The resulting bonded body was then annealed at 200° C. for 2 hours. The bonding strength after annealing was measured by the crack opening method. As a result, the glass substrate broke and the bonding strength was sufficiently high. In Example 2, the nitrogen concentration of the two SiO₂ films bonded to each other was measured by energy dispersive X-ray analysis, and the nitrogen concentration of the SiO₂ films was 1.7 atom%.

In Example 3, two glass substrates were bonded under the same bonding conditions as in Example 1 except that a glass substrate consisting of glass B was used as the first and second substrates. A wedge-like groove was formed at the outer edge of the bonding interface. The groove was formed between the edge-removed surfaces. The depth of the groove was 0.28 mm. When a razor blade was inserted into the groove, the two glass substrates were peeled off. Then, the two glass substrates that had been peeled off were bonded again, and the resulting bonded body was annealed at 200° C. for 2 hours. The bonding strength after annealing was measured by the crack opening method. As a result, the glass substrate broke and the bonding strength was sufficiently high. In Example 3, the nitrogen concentration of two SiO₂ films bonded to each other was measured by energy-dispersive X-ray analysis, and the nitrogen concentration of the SiO₂ films was 1.7 atom%.

In Example 4, two glass substrates were bonded under the same bonding conditions as in Example 1 except that a glass substrate consisting of glass C was used as the first and second substrates. A wedge-like groove was formed at the outer edge of the bonding interface. The groove was formed between the edge-removed surfaces. The depth of the groove was 280 µm. When a razor blade was inserted into the groove, the two glass substrates were peeled off. Then, the two glass substrates that had been peeled off were bonded again, and the resulting bonded body was annealed at 200° C. for 2 hours. The bonding strength after annealing was measured by the crack opening method. As a result, the glass substrate broke and the bonding strength was sufficiently high. In Example 4, the nitrogen concentration of the two SiO₂ films bonded to each other was measured by energy dispersive X-ray analysis, and the nitrogen concentration of the SiO₂ films was 1.9 atom%.

In Example 5, the two glass substrates were bonded under the same bonding conditions as in Example 4, except that the SiO₂ film was formed by the sputtering method, where the target was silicon oxide, rather than by the reactive sputtering method, where the target was metallic silicon. A wedge-like groove was formed on the outer edge of the bonding interface. The groove was formed between the edge-removed surfaces. The depth of the groove was 0.28 mm. When a razor blade was inserted into the groove, the two glass substrates were peeled off. Then, the two glass substrates that had been peeled off were bonded again, and the resulting bonded body was annealed at 200° C. for 2 hours. The bonding strength after annealing was measured by the crack opening method. As a result, the glass substrate broke and the bonding strength was sufficiently high. In Example 5, the nitrogen concentration of the two SiO₂ films bonded to each other was measured by energy dispersive X-ray analysis, and the nitrogen concentration of the SiO₂ films was 2.0 atom%.

In Example 6, a glass substrate and a sapphire substrate were bonded under the same bonding conditions as in Example 5, except that a sapphire substrate was prepared as the second substrate. A wedge-like groove was formed on the outer edge of the bonding interface. The groove was formed between the edge-removed surfaces. The depth of the groove was 0.28 mm. When a razor blade was inserted into the groove, the glass and sapphire substrates were peeled off. The glass and sapphire substrates that had been peeled off were then bonded again, and the resulting bonded body was annealed at 200° C. for 2 hours. The bonding strength after annealing was measured by the crack opening method. As a result, the glass substrate broke and the bonding strength was sufficiently high. In Example 6, the nitrogen concentration of the two SiO₂ films bonded to each other was measured by energy dispersive X-ray analysis, and the nitrogen concentration of the SiO₂ films was 2.0 atom%.

In Example 7, a glass substrate and a sapphire substrate were bonded under the same bonding conditions as in Example 4, except that a glass substrate consisting of glass D was prepared as the first substrate and a sapphire substrate was prepared as the second substrate. In plan view, the glass substrate was larger than the sapphire substrate and protruded outside the sapphire substrate. By holding the protruded part, the glass substrate and the sapphire substrate were peeled off. The glass and sapphire substrates that had been peeled off were then bonded again, and the resulting bonded body was annealed at 200° C. for 2 hours. The bonding strength after annealing was 1.2 J/m² as measured by the crack opening method. In Example 7, the nitrogen concentration of the two SiO₂ films bonded to each other was measured by energy dispersive X-ray analysis, and the nitrogen concentration of the SiO₂ films was 1.7 atom%.

In Example 8, two glass substrates were bonded under the same bonding conditions as in Example 1 except that the bonding surfaces of the glass substrates were modified by a sequential plasma method without forming a SiO₂ film on the bonding surface of each glass substrate. A wedge-like groove was formed on the outer edge of the bonding interface. The groove was formed between the edge-removed surfaces. The depth of the groove was 0.28 mm. When a razor blade was inserted into the groove, the two glass substrates were peeled off. Then, the two glass substrates that had been peeled off were bonded again, and the resulting bonded body was annealed at 200° C. for 2 hours. The bonding strength after annealing was 0.9 J/m² as measured by the crack opening method.

Note that the bonding strength after annealing was also 0.9 J/m² when the two glass substrates were bonded under the same bonding conditions as in Example 1 except that the bonding surfaces of the glass substrate were modified only by oxygen RIE without forming a SiO₂ film on the bonding surfaces of the glass substrates. Therefore, in the case of Example 8, that is, when the bonding surface of the glass with low SiO₂ content was modified by the sequential plasma method, the bonding strength was only as strong as when the bonding surfaces were modified only by oxygen RIE.

It is clear from comparing the evaluation results of Example 1 with those of Example 8 that when at least one of the two substrates to be bonded to each other is a glass with low SiO₂ content, the bonding strength can be improved by the sequential plasma method with a silicon oxide film being formed on the bonding surface of the glass.

In Example 9, two glass substrates were bonded under the same bonding conditions as in Example 3 except that the bonding surfaces of the glass substrates were modified by the sequential plasma method without forming a SiO₂ film on the bonding surfaces of the glass substrates. A wedge-like groove was formed on the outer edge of the bonding interface. The groove was formed between the edge-removed surfaces. The depth of the groove was 0.28 mm. When a razor blade was inserted into the groove, the two glass substrates were peeled off. Then, the two glass substrates that had been peeled off were bonded again, and the resulting bonded body was annealed at 200° C. for 2 hours. The bonding strength after annealing was 0.7 J/m² as measured by the crack opening method.

It is clear from comparing the evaluation results of Example 3 with those of Example 9 that the bonding strength can be improved by the sequential plasma method when at least one of the two substrates to be bonded together is a glass with low SiO₂ content and a silicon oxide film is formed on the bonding surface of the glass.

In Example 10, two glass substrates were bonded under the same bonding conditions as in Example 1 except that an Al₂O₃ film was formed by the reactive sputtering method instead of forming a SiO₂ film on the bonding surface of each glass substrate. A wedge-like groove was formed on the outer edge of the bonding interface. The groove was formed between the edge-removed surfaces. The depth of the groove was 0.28 mm. When a razor blade was inserted into the groove, the two glass substrates were peeled off. Then, the two glass substrates that had been peeled off were bonded again, and the resulting bonded body was annealed at 200° C. for 2 hours. The bonding strength after annealing was 0.4 J/m² as measured by the crack opening method.

It is clear from comparing the evaluation results of Example 1 with those of Example 10 that when at least one of the two substrates to be bonded to each other is a glass with low SiO₂ content, the sequential plasma method may fail to improve the bonding strength despite an aluminum oxide film being formed in advance on the bonding surface of the glass.

In Example 11, a glass substrate and a sapphire substrate were bonded under the same bonding conditions as in Example 6 except that the bonding surfaces were modified by the sequential plasma method without forming an SiO₂ film on the bonding surface of the glass substrate and the bonding surface of the sapphire substrate. A wedge-like groove was formed on the outer edge of the bonding interface. The groove was formed between the edge-removed surfaces. The depth of the groove was 0.28 mm. When a razor blade was inserted into the groove, the glass and sapphire substrates were peeled off. The glass and sapphire substrates that had been peeled off were then bonded again, and the resulting bonded body was annealed at 200° C. for 2 hours. The bonding strength after annealing was 0.7 J/m² as measured by the crack opening method.

It is clear from comparing the evaluation results of Example 6 with those of Example 11 that the bonding strength can be improved by the sequential plasma method when at least one of the two substrates to be bonded together is a glass with low SiO₂ content and a silicon oxide film is formed on the bonding surface of the glass.

In Example 12, a glass substrate and a sapphire substrate were bonded under the same bonding conditions as in Example 7 except that the bonding surfaces were modified by the sequential plasma method without forming a SiO₂ film on the bonding surface of the glass substrate and the bonding surface of the sapphire substrate. In plan view, the glass substrate was larger than the sapphire substrate and protruded outside the sapphire substrate. By holding the protruded part, the glass substrate and the sapphire substrate were peeled off. The glass and sapphire substrates that had been peeled off were then bonded again, and the resulting bonded body was annealed at 200° C. for 2 hours. The bonding strength after annealing was 0.8 J/m² as measured by the crack opening method.

It is clear from comparing the evaluation results of Example 7 with those of Example 12 that the bonding strength can be improved by the sequential plasma method when at least one of the two substrates to be bonded together is a glass with low SiO₂ content and a silicon oxide film is formed on the bonding surface of the glass.

In Example 13, a glass substrate made of glass A was used as the first and second substrates. On the bonding surfaces of glass substrates, a SiO₂ film was formed by the reactive sputtering method. Metallic silicon was used as a target of the reactive sputtering method. The bonding surfaces of the SiO₂ films were modified using oxygen plasma. Specifically, after irradiation with oxygen RIE, the bonding surfaces of the SiO₂ films were exposed to the atmosphere to attach OH groups. The treatment time of oxygen RIE was 180 seconds. Then, the two glass substrates were bonded through the two modified SiO₂ films. A wedge-like groove was formed on the outer edge of the bonding interface. The groove was formed between the edge-removed surfaces. The depth of the groove was 0.28 mm. When a razor blade was inserted into the groove, the two glass substrates were peeled off. Then, the two glass substrates that had been peeled off were bonded again, and the resulting bonded body was annealed at 200° C. for 2 hours. The bonding strength after annealing was measured by the crack opening method. As a result, the bonding strength was 1.0 J/m². In Example 13, when the nitrogen concentration of the two SiO₂ films bonded to each other was measured by energy-dispersive X-ray analysis, no nitrogen atoms were detected in the SiO₂ films.

It is clear from comparing the evaluation results of Example 1 with those of Example 13 that the bonding strength is improved by the inclusion of N in the SiO₂ film formed on the bonding surface.

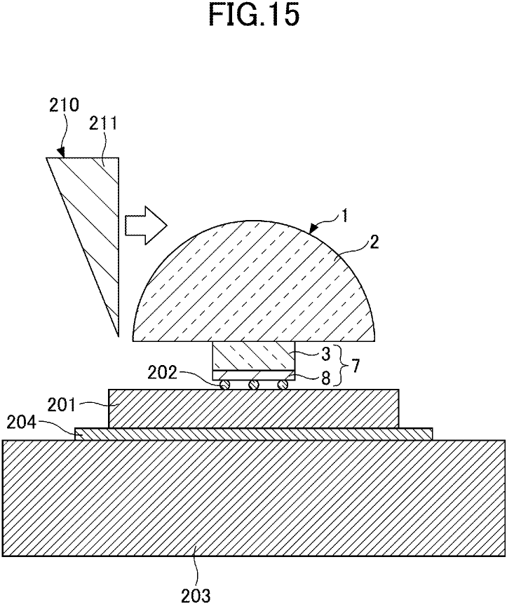

In Example 14, as illustrated in FIG. 14, a hemispherical lens 2 (hereafter, hemispherical lens 2) was prepared as the first base material 2. The diameter of the hemispherical lens 2 was 3 mm. A deep ultraviolet LED manufactured by Dowa Electronics was prepared as the light-emitting element 7. The light-emitting element 7 had a sapphire substrate 3, which was square-shaped with 1 mm sides and 0.4 mm thick, and a semiconductor light-emitting layer 8 formed on the sapphire substrate 3. The semiconductor light-emitting layer 8 was connected to a submount substrate 201 made of aluminum nitride ceramics with solder 202. On the bonding surface between the light-emitting element 7 and the hemispherical lens 2, SiO₂ films 5 and 6 were formed by the reactive sputtering method. As a target of the reactive sputtering method, metallic silicon was used. The bonding surfaces of SiO₂ films 5 and 6 were modified by a sequential plasma method. Specifically, the bonding surfaces of the SiO₂ films 5 and 6 were modified by performing oxygen RIE, nitrogen RIE, and irradiation of nitrogen radicals in this order, and exposed to the atmosphere to attach OH groups. The treatment time of oxygen RIE was 180 seconds, the treatment time of nitrogen RIE was 180 seconds, and the irradiation time of oxygen radicals was 15 seconds. Then, the light-emitting element 7 and the hemispherical lens 2 were bonded through the two modified SiO₂ films 5 and 6. When the bonded body 1 was viewed in plan view, the hemispherical lens 2 was larger than the light-emitting element 7, and protruded outside the light-emitting element 7. By holding the hemispherical lens 2 with tweezers and pulling it up in the direction perpendicular to the bonding surface, the hemispherical lens 2 and the light-emitting element 7 were peeled. Then, the peeled hemispherical lens 2 and the light-emitting element 7 were bonded again, and the resulting bonded body 1 was annealed at 200° C. for 2 hours. At this time, two bonded bodies 1 were prepared.

In Example 14, the measurement of the bonding strength between the hemispherical lens 2 and the light-emitting element 7 was performed using a die shear tester 210. The bonding strength measured using the die shear tester 210 is hereinafter referred to as a second bonding strength. The bottom surface of the submount substrate 201 was bonded to the glass substrate 203 with adhesive 204 to prepare a sample for the second bonding strength measurement. The sample was set in the die shear tester 210, and the tip of the indenter 211 of the die shear tester 210 was shifted 0.1 mm from the bonding interface between the hemispherical lens 2 and the light-emitting element 7 toward the hemispherical lens 2 side (upper side in FIG. 14), and the indenter 211 was moved in the horizontal direction (right direction in FIG. 14) at a speed of 0.2 mm per second. The second bonding strength is a load at the time of peeling when peeling has occurred at the bonding interface between the hemispherical lens 2 and the light-emitting element 7, and is greater than equal to a load at the time of destruction when destruction has occurred outside the bonding interface between the hemispherical lens 2 and the light-emitting element 7. When the second bonding strength was measured using one of the two bonded bodies 1 made in Example 14, the solder 202 connecting the light-emitting element 7 and the submount substrate 201 was broken by a 2.0 kg weight. The second bonding strength was 2.0 kg weight or more.

In Example 14, when the nitrogen concentration of two SiO₂ films 5 and 6 bonded to each other was measured by energy-dispersive X-ray analysis using a pair of bonded bodies 1 not used for the bonding strength measurement, the nitrogen concentration of the SiO₂ films 5 and 6 was 1.7 atom%.

In Example 15, the hemispherical lens 2 and the light-emitting element 7 were bonded as in Example 14, except that the two SiO₂ films 5 and 6 illustrated in FIG. 14 were not formed before bonding, as illustrated in FIG. 15. After bonding, the hemispherical lens 2 was held by tweezers and pulled up in the direction perpendicular to the bonding surface, which allowed the hemispherical lens 2 and the light-emitting element 7 to be peeled. Then, the peeled hemispherical lens 2 and the light-emitting element 7 were bonded again, and the resulting bonded body 1 was annealed at 200° C. for 2 hours. When the second bonding strength after the annealing was measured, the hemispherical lens 2 and the light-emitting element 7 were peeled at the bonding surface by a weight of 0.5 kg. The second bonding strength was 0.5 kg weight.

It is clear from comparing the evaluation results of Example 14 with those of Example 15 that when at least one of the two base materials to be bonded together is a glass with low SiO₂ content, and a silicon oxide film is formed on the bonding surface of the glass, the bonding strength can be improved by the sequential plasma method.

In Example 16, a quartz glass substrate (SiO₂ substrate) was prepared as the first base material and a sapphire substrate was prepared as the second base material. On the bonding surface of the sapphire substrate, a SiO₂ film was formed by the reactive sputtering method. As a target of the reactive sputtering method, metallic silicon was used. The bonding surfaces of the quartz glass substrate and the SiO₂ film were modified by a sequential plasma method. Specifically, the bonding surfaces of the quartz glass substrate and the SiO₂ film were modified by performing oxygen RIE, nitrogen RIE, and irradiation of nitrogen radicals in this order, and then exposed to the atmosphere to attach OH groups. The treatment time of oxygen RIE was 180 seconds, the treatment time of nitrogen RIE was 180 seconds, and the irradiation time of nitrogen radicals was 15 seconds. Then, the quartz glass substrate and the sapphire substrate were bonded. When the resulting bonded body was annealed at 200° C. for 2 hours, the quartz glass substrate and the sapphire substrate were peeled. In Example 16, the value of |α1-α2| exceeded 4.0 ppm/°C, and the thermal stress generated during the annealing was so great that the peeling occurred during the annealing. In Example 1 to Example 15, the value of |α1-α2| was 4.0 ppm/°C or less, and the thermal stress generated during the annealing was so small that the peeling did not occur during the annealing.

According to one aspect of the present disclosure, the bonding strength of glass with low SiO₂ content can be improved.

The bonded body, the method of manufacturing the bonded body, and the light-emitting device relating to the present disclosure have been described above, but the present disclosure is not limited to the above embodiments. Various alterations, modifications, substitutions, additions, deletions, and combinations are possible within the categories described in the claims. These also naturally fall within the technical scope of this disclosure.

What is claimed is:

1. A bonded body comprising:
a first base material;
a second base material;
an inorganic film for bonding the first base material and the second base material; and
a semiconductor layer formed on a surface opposite to a bonding surface of the second base material, the bonding surface of the second base material facing the first base material, wherein
the first base material is a glass with a SiO₂ content of 70 mol% or less, and
the inorganic film includes a silicon oxide film formed on a bonding surface of the first base material, the bonding surface of the first base material facing the second base material.

2. The bonded body according to claim 1, wherein a film thickness of the silicon oxide film formed on the bonding surface of the first base material is 1 nm or more and 100 nm or less.

3. The bonded body according to claim 1, wherein
the second base material is a glass with a SiO₂ content of 70 mol% or less, and
the inorganic film includes a first silicon oxide film formed on the bonding surface of the first base material and a second silicon oxide film formed on the bonding surface of the second base material.

4. The bonded body according to claim 1, wherein
the second base material is an inorganic single crystal or an inorganic polycrystal with a SiO₂ content of 70 mol% or less, and
the inorganic film includes a first silicon oxide film formed on the bonding surface of the first base material and a second silicon oxide film formed on the bonding surface of the second base material.

5. The bonded body according to claim 4, wherein a total thickness of the first silicon oxide film and the second silicon oxide film is 1 nm or more and 200 nm or less.

6. The bonded body according to claim 1, wherein a difference in a mean linear expansion coefficient between the first base material and the second base material at 50° C. to 200° C. is 0.0 ppm/°C or more and 4.0 ppm/°C or less.

7. The bonded body according to claim 1, wherein the second base material and the semiconductor layer constitute a light-emitting element.

8. The bonded body according to claim 7, wherein the light-emitting element is an ultraviolet light-emitting element.

9. The bonded body according to claim 7, wherein the first base material is a lens.

10. The bonded body according to claim 9, wherein the first base material is a spherical lens having a convex surface opposite to the bonding surface of the first base material.

11. The bonded body according to claim 1, wherein a sum of a product of a Young’s modulus and a maximum thickness of the first base material and a product of a Young’s modulus and a maximum thickness of the second base material is 70 GPa·mm to 300 GPa-mm.

12. The bonded body according to claim 1, wherein a wedge-like groove is formed at an outer edge of a bonding interface between the first base material and the second base material.

13. The bonded body according to claim 12, wherein a depth of the groove is 0.05 mm to 0.5 mm.

14. The bonded body according to claim 1, wherein in plan view, the first base material is larger than the second base material and protrudes outside the second base material.

15. The bonded body according to claim 1, wherein a nitrogen concentration of the silicon oxide film measured by energy-dispersive X-ray analysis is 1 atomic% or more.

16. A method of manufacturing the bonded body according to claim 9, wherein the bonding surface of the lens facing the second base material before bonding the lens to the second base material is a convex curved surface, and a maximum difference in height of the bonding surface of the lens is 5 nm to 400 nm.

17. A method of manufacturing the bonded body according to claim 9, wherein at least a region overlapping the second base material after bonding is a convex curved surface, and a maximum difference in height of the region is 5 nm to 200 nm, the region being a part of the bonding surface of the lens facing the second base material before bonding the lens to the second base material.

18. A light-emitting device comprising:
the bonded body according to claim 1; and
a container configured to house the bonded body, wherein the second base material and the semiconductor layer constitute a light-emitting element.

19. The bonded body according to claim 9, wherein a nitrogen concentration of the silicon oxide film measured by energy-dispersive X-ray analysis is 1 atomic% or more.

20. A light-emitting device comprising:
the bonded body according to claim 15; and
a container configured to house the bonded body, wherein the second base material and the semiconductor layer constitute a light-emitting element.
